(19) United States
(12) Patent Application Publication
(10) Pub. No.: US 2017/0271615 A1
(43) Pub. Date: Sep. 21, 2017

(54) SCREEN-PRINTING MASK, METHOD FOR FABRICATING THE SAME, AND RELATED PACKAGING METHOD

(71) Applicant: BOE TECHNOLOGY GROUP CO., LTD., Beijing (CN)

(72) Inventor: ZHENGYIN XU, Beijing (CN)

(21) Appl. No.: 15/305,425

(22) PCT Filed: Sep. 15, 2015
(86) PCT No.: PCT/CN2015/089657

§ 371 Date: Oct. 20, 2016

(51) Int. Cl. H01L 51/52; G03F 1/22; H01L 51/56

(52) U.S. Cl. CPC H01L 51/5246; H01L 51/56; G03F 1/22

(57) ABSTRACT

The present disclosure provides a screen-printing mask for manufacturing a substrate for packaging a display panel. The screen-printing mask includes a first pattern with a continuous loop shaped groove surrounding a first area; and a second pattern with grooves forming a discontinuous loop surrounding the first pattern, wherein the first pattern is configured to form a sealing loop for the display panel, and the second pattern is configured to form a supporting loop to provide support for the first pattern in a display panel packaging process.

### FIELD OF THE INVENTION

The present invention generally relates to the display technologies and, more particularly, relates to a screen-printing mask, method for fabricating the same, and a related packaging method.

### BACKGROUND

Organic light-emitting diode (OLED) display products have become widely used in small and mid-sized display devices. Compared to conventional liquid crystal display (LCD) products, OLED display products are generally lighter and thinner. OLED display products also have sharp color contrasts, and can be used in flexible and transparent display products.

The OLED layer in an OLED display product may be susceptible to erosion by oxygen and moisture. Often, frit packaging is used for the packaging of small and mid-sized display devices because of its high resistivity to oxygen and moisture. Frit is often mixed with glass powder to form solutions with certain viscosities and then coated on the packaging glass to form certain packaging patterns on a substrate. The solvent of the solutions can be removed or evaporated by a heating process. Another packaging glass or substrate is then placed onto the mixture. Laser radiation with certain wavelengths is often used to melt or solder the mixture so that the two substrates are bonded together and the OLED layer is encapsulated between the two substrates. A cutting process is then applied to remove the edges of the soldered packaging glasses.

However, frit packaging may be expensive and may be susceptible to cracking due to packaging stress during the packaging process. As a result, the packaged OLED layer may be exposed to air and moisture and be damaged.

### BRIEF SUMMARY OF THE DISCLOSURE

The present disclosure provides a screen-printing mask and a related packaging structure. By using the screen-printing mask to form the packaging structure, damages to the frit sealing loop caused by cutting can be reduced and fabrication yield of frit packaging can be improved. Fabrication cost of the frit packaging can be reduced.

One aspect of the present disclosure includes a screen-printing mask for manufacturing a substrate for packaging a display panel. The screen-printing mask includes a first pattern with a continuous loop shaped groove surrounding a first area; and a second pattern with grooves forming a discontinuous loop surrounding the first pattern, wherein the first pattern is configured to form a sealing loop for the display panel, and the second pattern is configured to form a supporting loop to provide support for the first pattern in a display panel packaging process.

Optionally, the groove of the first pattern includes continuously connected shapes with a width of about 0.4 mm to about 1 mm; the grooves of the second pattern includes discrete shapes with a width of about 0.2 mm to about 0.5 mm; and a distance between the first pattern and the second pattern may be about 0.1 mm to about 0.3 mm.

Optionally, the continuous loop is a rectangular shaped loop; the discontinuous loop is a rectangular shaped loop; and each side of the continuous loop is parallel to a corresponding side of the discrete loop.

Optionally, the grooves of the second pattern have a strip shape, a dot shape, or a combination thereof.

Another aspect of the present disclosure includes a method for forming a screen-printing mask for packaging a display panel, the screen-printing mask having a first pattern with a continuous loop shaped groove surrounding a first area, and a second pattern with grooves forming a discontinuous loop surrounding the first pattern, the first pattern being configured to form a sealing loop for the display panel and the second pattern being configured to form a supporting loop to provide support for the first pattern in a display panel packaging process, includes providing a substrate; applying a layer of photosensitive resin on the substrate; patterning the layer of photosensitive resin to form the first pattern and the second pattern in the layer of photosensitive resin; and hardening patterned layer of photosensitive resin.

Optionally, a process to pattern the layer of photosensitive resin includes a photolithography process.

A method for packaging a display panel, using a screen-printing mask with a first pattern with a continuous loop shaped groove surrounding a first area and a second pattern with grooves forming a discontinuous loop surrounding the first pattern, the first pattern being configured to form a sealing loop for the display panel and the second pattern being configured to form a supporting loop to provide support for the first pattern in a display panel packaging process, includes: applying frit on the screen-printing mask to cover at least the first pattern and the second pattern; and scraping the frit such that only the groove of the first pattern and the grooves of the second pattern are filled with frit. The method further includes forming a continuous frit sealing loop through the first pattern and a discontinuous frit supporting loop through the second pattern on a first substrate, the continuous frit sealing loop surrounding a first area on the first substrate; aligning the first substrate with a second substrate containing an OLED structure and contacting the first substrate with the second substrate so that the OLED structure of the second substrate is placed in an area corresponding to the first area on the first substrate; and scanning the continuous frit sealing loop with laser to bond the first substrate and the second substrate.

Optionally, the method further includes cutting bonded first substrate and second substrate along periphery of the discontinuous frit supporting loop, along a direction of the discontinuous frit supporting loop, or along an area between the discontinuous first supporting loop and the continuous frit sealing loop to remove excessive portions of the first substrate and the second substrate.

Optionally, forming the continuous frit sealing loop through the first pattern and the discontinuous frit supporting loop through the second pattern on the first substrate includes flipping the mask for screen printing onto the first substrate to transfer the continuous frit sealing loop through the first pattern and transfer the discontinuous frit supporting loop through the second pattern.

Optionally, the method further includes a baking process to harden the continuous frit sealing loop and the discrete frit supporting loop after the continuous frit sealing loop and the discrete frit supporting loop are formed on the first substrate.

Optionally, a baking temperature is about 350 degrees Celsius to about 450 degrees Celsius.

Optionally, thicknesses of the continuous frit sealing loop and the discrete frit supporting loop is same.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates the top view of an exemplary screen-printing mask according to the embodiments of the present disclosure;

FIG. 2 illustrates an exemplary process for forming a display apparatus using the screen-printing mask according to the embodiments of the present disclosure;

FIG. 3 illustrates a cross-section view of an exemplary packaging structure according to the embodiments of the present disclosure;

FIG. 4 illustrates another cross-section view of the exemplary packaging structure according to the embodiments of the present disclosure; and

FIG. 5 illustrates a cross-section view of the exemplary display apparatus according to the embodiments of the present disclosure.

### DETAILED DESCRIPTION

For those skilled in the art to better understand the technical solution of the invention, reference will now be made in detail to exemplary embodiments of the invention, which are illustrated in the accompanying drawings. Wherever possible, the same reference numbers will be used throughout the drawings to refer to the same or like parts.

It should be noted that in this disclosure, the figures are only for illustrative purposes and do not reflect the true ratios or dimensions of the actual objects.

The packaging stress in the frit packaging process is mainly from the mismatch of thermal expansion coefficients between the frit and the glass powder. In addition, the pressure from the cutting blade during the mechanical cutting process may cause deterioration in the assembly. Thus, the cutting margins have to be sufficiently large to avoid the assembly from being adversely affected by the cutting process. Increased cutting margins limit fabrication yield of the frit packaging, which may increase the fabrication cost.

One aspect of the present disclosure provides a screen-printing mask that can be used in the frit packaging process.

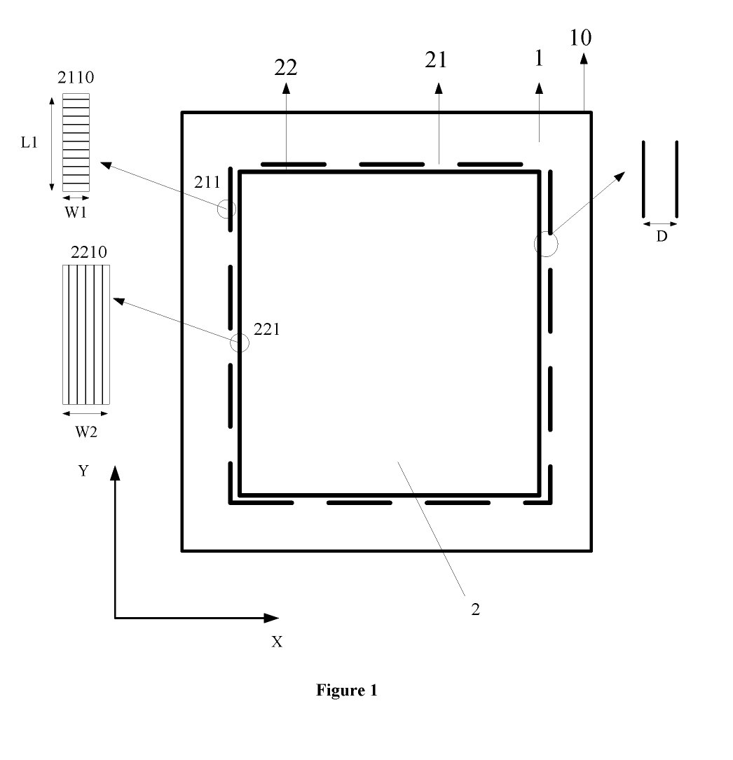

FIG. 1 illustrates the top view of the disclosed screen-printing mask 1. The screen-printing mask 1 may be made of any suitable material such as resin. The screen-printing mask 1 may include a first opening region 21 and a second opening region 22. The first opening region 21 may be used to form a discrete or discontinuous frit supporting structure. The second opening region 22 may be used to form a continuous frit sealing loop.

As shown in FIG. 1, the screen-printing mask 1 may include a frame portion 10 and a screen portion. The frame portion 10 may be made of suitable metal such as Al alloy. The frame portion 10 may enclose the screen portion, which includes the features or patterns enclosed by the frame portion 10. The screen portion may include a substrate, e.g., a dense net made of sufficiently thin steel wires and/or sufficiently thin nylon wires. When in operation, suitable material such as photosensitive resin may be coated on the net in the area defined by the frame portion 10 to form a resin film, which covers holes and wires of the screen. A patterning process, such as a photolithography process, may be used to remove desired portions of the photosensitive resin film to form the first opening region 21 and the second opening region 22.

As shown in FIG. 1, the first opening region 21 may have an overall rectangular-loop shape and may include discrete or discontinuous patterns or grooves along X direction and Y direction. X direction is different from Y direction. For example, as shown in FIG. 1, the first opening region 21 may include a plurality of discrete or discontinuous patterns or shapes, such as strips or dots, along the X direction and the Y direction. In one embodiment, the discrete shapes or grooves may be strips. In other embodiments, the grooves may have any suitable shapes such as dots, triangles, etc., according to different designs or applications. The first opening region 21 may also have other overall shapes such as an oval-loop shape, a circular-loop shape, or other polygon-loop shapes. The overall shape of the first opening region 21 may be determined or adjusted according to different applications or designs and is not limited by the embodiments of the present disclosure. In one embodiment, as shown in FIG. 1, the X direction may be perpendicular to the Y direction.

In one embodiment, the grooves of the first opening region 21 may have a strip shape and the plurality of strips 211 of the first opening region 21 may form the overall rectangular-loop shape. Each strip may have a width of about 0.2 mm to about 0.5 mm. The length of each strip 211 may be adjusted according to different applications or designs and should not be limited by the embodiments herein. In one embodiment, the length of each strip 211 may be about 3 mm to about 10 mm. For example, 2110 may be an enlarged view of a strip 211 in the first opening region along the Y direction. The width of 211 along the X direction, W1, may be about 0.2 mm to about 0.5 mm. The length of the strip 211 along the Y direction, L1, may be about 3 mm to about 10 mm. Preferably, the length of the strip 211 along the Y direction, L1, may be about 1 mm to about 5 mm. The distance between adjacent strips may be about 3 mm to about 10 mm. It should be noted that because the shape of the strips of the first opening region and the distance between two adjacent strips may be subjected to the different designs or applications, the actual values of the width and lengths of a strip can be adjusted according to difference designs. It should also be noted that the distance between two strips should not be so large that the discrete frit supporting loop of the frit strips 211 can't provide sufficient support to the continuous frit sealing loop 22 in the subsequent cutting process. By using the discrete pattern 21, the material, e.g., frit, used in the frit packaging process can be reduced and fabrication cost can be reduced.

The second opening region 22 may have an overall rectangular-loop shape and may be continuous along the X direction and the Y direction. That is, as shown in FIG. 1, the second opening region 22 may include four strips connected continuously or one continuous groove along the X direction and the Y direction to form an overall closed loop. Each strip may have a width of about 0.4 mm to about 1 mm. For example, 2210 may be an enlarged view of a portion of the strip 221 in the second opening region along the Y direction. The width of 221 along the X direction, W2, may be about 0.4 mm to about 1 mm. The length of the strip 221 and the central area 2 enclosed by the second opening region 22 may be adjusted according to the size of the OLED structure to be packaged. In certain other embodiments, the second opening region 22 may also have other overall shapes such as an oval-loop shape, a circular-loop shape, or other polygon-loop shapes. The overall shape of the second opening region 22 may be determined or adjusted according to different applications or designs and is not limited by the embodiments of the present disclosure.

In one embodiment, the second opening region 22 may be fully inside the area defined by the first opening region 21. Each side of the second opening region 22, along the X direction and along the Y direction, may be parallel to the corresponding side of the first opening region 21. A distance between the first opening region and the second opening region, D, may be about 0.1 mm to about 0.3 mm. The central region surrounded by the first opening region 21 and the second opening region 22 may correspond to the area for placing the OLED structure in the subsequent packaging process. That is, the central area 2 may need to be larger than the area of the OLED structure.

Another aspect of the present disclosure provides a method for forming a screen-printing mask.

A screen with a frame may be provided at the beginning of the manufacturing process. The screen may include a substrate, e.g., a dense net made of sufficiently thin steel wires and/or nylon wires, defined by the frame. Photosensitive materials such as photosensitive resin may be applied on the substrate to form a uniform film. A patterning process may be used to form the first opening region 21 and the second opening region 22 in the resin film.

The patterning process to form the screen-printing mask 1 may be a photolithography process. A patterning mask may be used to define the portions of the resin film, corresponding to the first opening region 21 and the second opening region 22, to be removed. The patterning mask may be made of quartz and may have corresponding patterns for defining the first opening region 21 and the second opening region 22. The patterning mask may be a positive mask, where the patterns corresponding to the first opening region 21 and the second opening region 22 may be transparent or clear, and the rest of the patterning mask may be deposited with chromium. The patterning mask may also be a negative mask, where the patterns corresponding to the first opening region 21 and the second opening region 22 may be deposited with chromium, and the rest of the patterning mask may be transparent.

In one embodiment, the patterning mask may be a negative mask. Photosensitive resin may be spinned onto the substrate to form a resin film. The patterning mask may be applied on the resin film. Patterns or shades corresponding to the first opening region 21 and the second opening region 22 may cover portions of the resin film. The rest of the resin film may be covered by the transparent portions of the patterning mask.

Further, ultraviolet light may be used to irradiate on the patterning mask. The portions of the resin film covered by the transparent portions of the patterning mask may be irradiated by the ultraviolet light and may form crosslinks in the photosensitive resin. Further, the patterning mask may be removed and the resin film may be developed in a suitable developing solution. The portions of the resin film corresponding to the first region 21 and the second region 22, previously covered by the patterns of the patterning mask, may be removed to form the first opening region 21 and the second opening region 22. The portions of the resin film with formed crosslinks may remain. Thus, the screen-printing mask 1 with the first opening region 21 and the second opening region 22 may be formed. It should be noted that, the specific type to form the screen-printing mask 1 may be determined according to different applications or designs and should not be limited by the embodiments of the present disclosure.

By using the disclosed screen-printing mask 1, the first opening region 21 and the second opening region 22 can be formed. The first opening region 21 may include a discrete or discontinuous pattern along the X direction and the Y direction, and the second opening region 22 may include a continuous pattern along the X direction and the Y direction. The first opening region 21 and the second opening region 22 may be used for transferring patterns of the continuous frit sealing loop and the discrete frit supporting loop onto a first substrate for the packaging of a display panel, containing the OLED structure.

Another aspect of the present disclosure provides a method for forming a display apparatus using the disclosed screen-printing mask. The display apparatus may be any suitable devices containing a light-emitting portion to be protected from oxygen and moisture. In one embodiment, the display apparatus is a display panel.

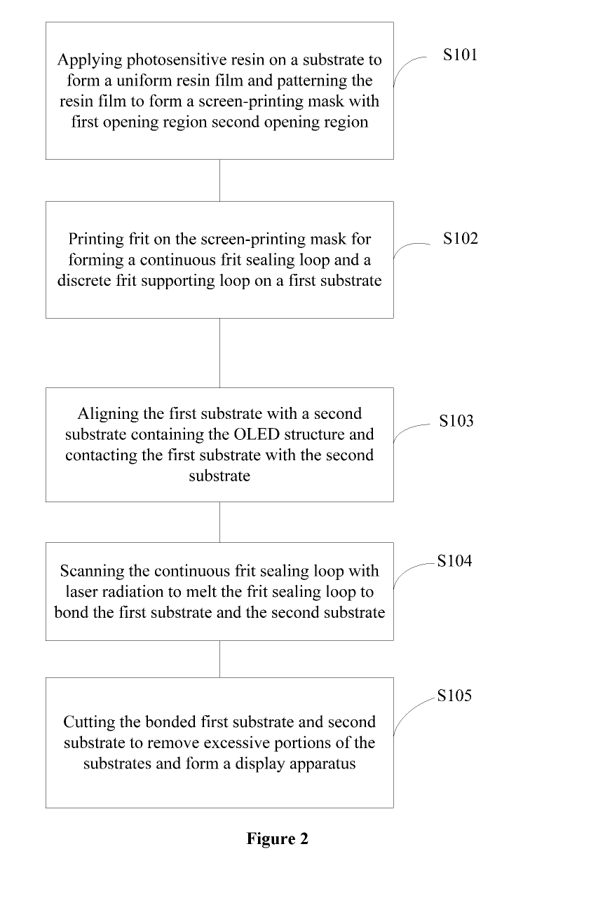

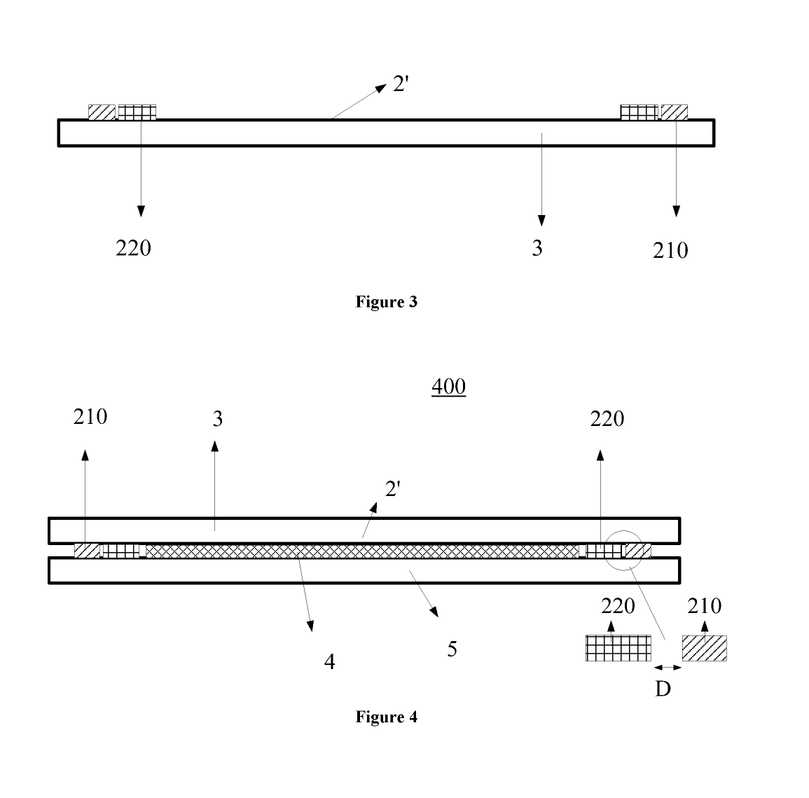

FIG. 2 illustrates an exemplary process to form a display apparatus using the screen-printing mask 1. The process may include steps S101 to S105. FIGS. 3 to 5 illustrate certain portions of the display apparatus.

In step 101, photosensitive resin may be applied on a substrate enclosed by a frame to form a uniform resin film. The resin film may be patterned to form a screen-printing mask 1 with first opening region and second opening region.

Any suitable types of photosensitive resin may be applied on the substrate to form a uniform resin film. The substrate may be a dense net made of sufficiently thin metal wires and/or nylon wires. The photosensitive resin (not shown) may be applied on the substrate through any suitable coating process such as spinning or spraying. The frame may define the shape and surface area of the resin film. In one embodiment, the resin film may be solidified. The solidification process may be any suitable process such as a pre-bake on a hot-plate or an illumination process by radiation of certain wavelengths.

Further, the resin film may be patterned through a suitable patterning process such as photolithography. The patterning process to form the screen-printing mask 1 may be a photolithography process. The patterning mask may be used to define the portions of the resin film, corresponding to the first opening region 21 and the second opening region 22, to be removed, a shown in FIG. 1. The patterning mask may be made of quartz and may have corresponding patterns for defining the first opening region 21 and the second opening region 22. In one embodiment, the patterning mask may be a negative mask. After the resin film is formed, the patterning mask may be applied on the resin film. Patterns or shades corresponding to the first opening region 21 and the second opening region 22 may cover portions of the resin film. The rest of the resin film may be covered by the transparent portions of the patterning mask.

Further, ultraviolet light may be used to irradiate on the patterning mask. The portions of the resin film covered by the transparent portions of the patterning mask may be irradiated by the ultraviolet light and may form crosslinks in the photosensitive resin. Further, the patterning mask may be removed and the resin film may be developed in a suitable developing solution. The portions of the resin film corresponding to the first region 21 and the second region 22, previously covered by the patterns of the patterning mask, may be removed to form the first opening region 21 and the second opening region 22. The portions of the resin film with formed crosslinks may remain. Thus, the screen-printing mask 1 with the first opening region 21 and the second opening region 22 may be formed.

The developed resin film, with the first opening region 21 and the second opening region 22, may be further solidified through a suitable hardening process such as being heated on a hot plate for a post-bake or being illuminated by radiation of certain wavelengths, to harden the resin and form a screen-printing mask 1, i.e., a mold, shown in FIG. 1. The screen-printing mask 1 may include first opening region 21 and second opening region 22. The first opening region 21 may be used to form a frit supporting structure. The second opening region 22 may be used to form a frit sealing loop.

It should be noted that the patterning process described in step S101 may be any suitable patterning process for forming the screen-printing mask 1. The material to form the screen-printing mask 1 can be any suitable photosensitive material capable of being solidified.

In step S102, as shown in FIG. 3, frit may be printed on the screen-printing mask 1 for forming a continuous frit sealing loop 220 and a discrete frit supporting loop 210 on a first substrate 3.

Frit may be printed onto the screen-printing mask 1 to cover the first opening region 21 and the second opening region 22. Further, a scraping component or scraper may be used to scrape the frit such that only the first opening region 21 and the second opening region 22 may be filled with frit. Other areas on the screen-printing mask 1, except for the first opening region 21 and the second opening region 22, may not be covered with frit. The screen-printing mask 1, with frit filled in the first opening region 21 and the second opening region 22, may be flipped and placed on the first substrate 3. Thus, the frit in the first opening region 21 and the second opening region 22 may be transferred onto the first substrate 3 to form patterns of the continuous frit sealing loop 220 and the discrete frit supporting loop 210 on the first substrate 3, as shown in FIG. 3. The pattern of the discrete frit supporting loop 210 may correspond to the pattern of the first opening region 21 on the screen-printing mask 1. The pattern of the continuous frit sealing loop 220 may correspond to the pattern of the second opening region 22 on the screen-printing mask 1.

The continuous frit sealing loop 220 and the discrete frit supporting loop 210 may be solidified at a suitable temperature to be hardened. In one embodiment, the solidification may be through a baking process. The baking temperature may be about 350 degrees Celsius to about 450 degrees Celsius. The thicknesses of the continuous frit sealing loop 220 and the discrete frit supporting loop 210, after a baking or hardening process, may be about 5 μm to about 20 μm. The thickness of the continuous frit sealing loop 220 and the thickness of the discrete frit supporting loop 210 may be substantially the same such that a second substrate 5 can have close contact with the continuous frit sealing loop 220 and the discrete frit supporting loop 210 in the subsequent packaging process. The baking temperature may be set according to the composition of the specific frit, the patterns or thicknesses of the continuous frit sealing loop 220 and the discrete frit supporting loop 210 and should not be limited by the disclosed embodiments herein.

The baking or hardening process may enable the continuous frit sealing loop 220 and the discrete frit supporting loop 210 to have desired mechanical strength and be bonded on the first substrate 3.

In step S103, as shown in FIG. 4, the first substrate 3 may be aligned with a second substrate 5 containing an OLED structure 4 and to contact the second substrate 5.

The second substrate 5 may contain the OLED structure 4 for displaying images. Certain aligning process may be performed to align the first substrate 3 with the second substrate 5. The first substrate 3 may contact the second substrate 5 after the aligning process. The OLED structure 4 may be placed in the area 2′ fully enclosed by the continuous frit sealing loop 220. The area 2′ may correspond to the central area 2 in the screen-printing mask 1 (FIG. 1).

The continuous frit sealing loop 220 may surround the OLED structure 4. The discrete frit supporting loop 210 may surround the OLED structure 4 and the continuous frit sealing loop 220. Both of the continuous frit sealing loop 220 and the discrete frit sealing loop 210 may be in contact with the second substrate 5 and the continuous frit sealing loop 220 may form a hermetic seal around the OLED structure 4. The OLED structure 4 may not have contact with the continuous frit sealing loop 220. The space between the first substrate 3 and the second substrate 5 and sealed by the continuous frit sealing loop 220 may be vacuumed through a vacuuming process.

For illustrative purposes, specific components in the OLED structure 4 such as thin-film transistor layer or supporting structures are not depicted here for viewing simplicity.

In step S104, laser radiation may be used to melt the continuous frit sealing loop 220 to bond the first substrate 3 and the second substrate 5.

Suitable laser radiation, such as infrared radiation, may be used to scan the continuous frit sealing loop 220 and melt the continuous frit sealing loop 220. In some embodiments, the infrared radiation may have a wavelength about 810 nm. The continuous frit sealing loop 220 may be melted to form a bond between the first substrate 3 and the second substrate 5. A sealed space can be formed by the melted continuous frit sealing loop 220 and vacuum can be maintained in the sealed space between the first substrate 3 and the second substrate 5. The continuous frit sealing loop 220, may enable the sealed space to have a constant and uniformed thickness, i.e., about 4 μm to about 15 μm according to the thickness of the continuous frit sealing loop 220, such that the OLED structure 4 can be protected and supported. After melted by the laser radiation, the thickness of the continuous frit sealing loop 220 may be reduced by about 5% to about 20%.

In step S105, the bonded first substrate 3 and the second substrate 5 may be cut along the periphery of the discrete frit supporting loop 210, along the discrete frit supporting loop 210, or along the area between the continuous frit sealing loop 220 and the discrete frit supporting loop 210 to remove excessive portions of the substrates and form a display apparatus.

A suitable cutting process may be used to cut off excessive portions of the bonded first substrate 3 and the second substrate 5 to form the display apparatus. The OLED structure 4 is packaged between the first substrate 3 and the second substrate 5 and sealed by the continuous frit sealing loop 220.

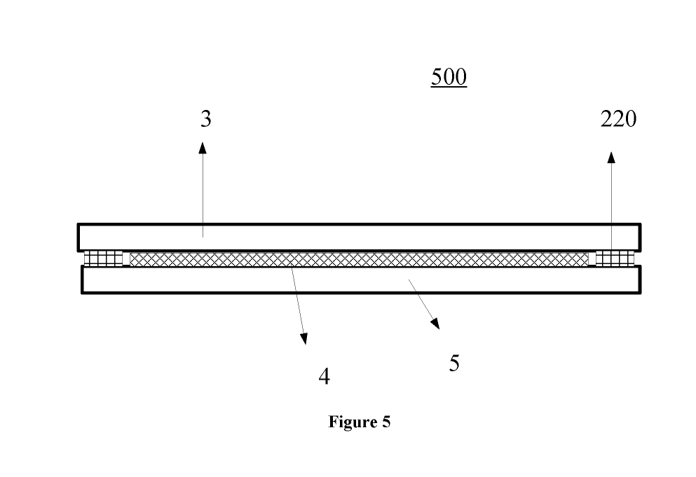

In one embodiment, the cutting blade may move along the direction of the discrete frit supporting loop 210 to remove the excessive portions of the bonded first substrate 3 and the second substrate 5 and form the display apparatus 500, as shown in FIG. 5. In embodiments of the present disclosure, most of the stress or pressure imposed by the cutting process may be applied on the discrete frit supporting loop 210 such that the continuous frit sealing loop 220 may be less susceptible to any adverse effect caused by the stress or pressure during the cutting process.

In another embodiment, the cutting blade may move along the area between the continuous frit sealing loop 220 and the discrete frit supporting loop 210 to form the display apparatus 500. In this case, the stress or pressure imposed by the cutting process is evenly distributed between the continuous frit sealing loop 220 and the discrete frit supporting loop 210 such that the continuous frit sealing loop 220 may also be less susceptible to any adverse effect caused by the stress or pressure.

Thus, using the disclosed screen-printing mask 1, only one patterning process is required to form the continuous frit sealing loop 220 and the discrete frit supporting loop 210. Because of the discrete pattern, the material used to form the discrete frit supporting loop 210 can be adjusted. During the cutting process, adverse effect on the continuous frit sealing loop 220 may be greatly reduced. In embodiments of the present disclosure, the fabricating process can be simpler with lower cost, and the fabrication yield of the frit packaging may be improved.

The disclosed screen-printing mask may be used for mass production of display apparatus 500. A large screen-printing mask with a plurality of screen-printing masks 1 may be used to fabricate a plurality of the disclosed display apparatus 500. The plurality of screen-printing masks 1 may be repeating along the X direction and along the Y direction. At the beginning of the fabrication process, photosensitive resin may be used to form a plurality of screen-printing masks 1 with first opening region and second opening region on each of the screen-printing mask. Frit may be printed on each one of the screen-printing masks 1, and each screen-printing mask 1 may be flipped and placed on a first substrate to form a continuous frit sealing loop and a discrete frit support loop on the first substrate. The continuous frit sealing loop and the discrete frit supporting loop may be baked to harden. A second substrate with an OLED structure may be aligned with the first substrate to contact the firs substrate. Each one of the OLED structures may be surrounded by the corresponding continuous frit sealing loop. The space in the space sealed by the continuous frit sealing loop may be vacuumed.

Further, laser radiation may be used to solder or melt the continuous frit sealing loop such that the second substrate and the first substrate can be bonded together and each continuous frit sealing loop may form a hermetic seal between the corresponding first substrate and the second substrate, and around the corresponding OLED structure. Further, a cutting process may be used to remove the excessive portions or cutting margins of each bonded first substrate and second substrate. The cutting blade may cut along the periphery of each discrete frit supporting loop, along the discrete frit supporting loop, or along the area between each continuous frit sealing loop and the corresponding discrete frit supporting loop. Thus, a plurality of display apparatus 500 may be manufactured.

The first substrate may be any suitable transparent substrate or cover layer such as a glass substrate. The second substrate may be any suitable substrate with the OLED structure and other related components, such as a glass substrate.

FIG. 4 shows the cross-section view of a packaging structure 400 provided by the present disclosure. The packaging structure 400 may include a first substrate 3, a second substrate 5, an OLED structure 4, a continuous frit sealing loop 220, and a discrete frit supporting loop 210. The first substrate 3 and the second substrate 5 may be bonded by the continuous frit sealing loop 220 between the first substrate 3 and the second substrate 5. The continuous frit sealing loop 220 may be melted or soldered to form a sealed space between the first substrate 3 and the second substrate 5 such that the OLED structure 4 can be encapsulated in the seal space. The seal space may be vacuumed. The OLED may not have contact with the continuous frit sealing loop 220. The discrete frit supporting loop 210 may surround the continuous frit sealing loop 220 to provide support to the continuous frit sealing loop 220 during a cutting process such that damages to the continuous frit sealing loop 220 caused by the cutting process can be reduced. The distance D between the continuous frit sealing loop 220 and the discrete frit supporting loop 210 may be about 0.1 mm to about 0.3 mm. The thickness between the first substrate 3 and the second substrate 4 may be about 4 μm to about 15 μm before being melted and may be reduced by about 5% to about 20% after being melted.

FIG. 5 shows a cross-section view of the display apparatus 500 formed from the packaging structure 400 shown in FIG. 4. The display apparatus may include a first substrate 3, a second substrate 5, an OLED structure 4, and a continuous frit sealing loop 220. The first substrate 3 and the second substrate 5 may be bonded by the continuous frit sealing loop 220 between the first substrate 3 and the second substrate 5. The continuous frit sealing loop 220 may be melted or soldered to form a sealed space between the first substrate 3 and the second substrate 5 such that the OLED structure 4 can be encapsulated in the seal space. The seal space may be vacuumed. A front surface of the OLED structure 4 may be contacting the first substrate 3 and a back surface of the OLED structure 4 may be contacting the second structure. The OLED may not contact the continuous frit sealing loop 220. The thickness between the first substrate 3 and the second substrate 5 may be about 4 μm to about 19.5 μm.

The display apparatus according to the embodiments of the present disclosure can be used in any product with display functions such as a display panel, a television, an LCD, an OLED, an electronic paper, a digital photo frame, a mobile phone, and a tablet computer.

Thus, by using the disclosed screen-printing mask, discrete frit supporting loop may be formed to provide support for the continuous frit sealing loop during the cutting process so that adverse effect to the continuous frit sealing loop can be reduced during the cutting process. In embodiments of the present disclosure, fabrication cost of the frit packaging may be reduced and fabrication yield of the frit packaging can be improved. Further, in the mass production of the related display apparatus, because the continuous frit sealing loops are less susceptible to cutting damages, cutting margins between adjacent display apparatus may be reduced. Thus, fabrication yield can be further improved and fabrication cost can be further reduced.

It should be understood that the above embodiments disclosed herein are exemplary only and not limiting the scope of this disclosure. Without departing from the spirit and scope of this invention, other modifications, equivalents, or improvements to the disclosed embodiments are obvious to those skilled in the art and are intended to be encompassed within the scope of the present disclosure.

1-12. (canceled)

13. A screen-printing mask for manufacturing a substrate for packaging a display panel, comprising:
a first pattern with a continuous loop shaped groove surrounding a first area; and
a second pattern with grooves forming a discontinuous loop surrounding the first pattern,
wherein the first pattern is configured to form a sealing loop for the display panel, and the second pattern is configured to form a supporting loop to provide support for the first pattern in a display panel packaging process.

14. The screen-printing mask according to claim 13, wherein:
the groove of the first pattern includes continuously connected shapes with a width of about 0.4 mm to about 1 mm;
the grooves of the second pattern includes discrete shapes with a width of about 0.2 mm to about 0.5 mm; and
a distance between the first pattern and the second pattern may be about 0.1 mm to about 0.3 mm.

15. The screen-printing mask according to claim 13, wherein:
the continuous loop is a rectangular shaped loop;
the discontinuous loop is a rectangular shaped loop; and
each side of the continuous loop is parallel to a corresponding side of the discrete loop.

16. The screen-printing mask according to claim 14, wherein the grooves of the second pattern have a strip shape, a dot shape, or a combination thereof

17. A method for forming a screen-printing mask for packaging a display panel, the screen-printing mask having a first pattern with a continuous loop shaped groove surrounding a first area, and a second pattern with grooves forming a discontinuous loop surrounding the first pattern, the first pattern being configured to form a sealing loop for the display panel and the second pattern being configured to form a supporting loop to provide support for the first pattern in a display panel packaging process, includes:
providing a substrate;
applying a layer of photosensitive resin on the substrate;
patterning the layer of photosensitive resin to form the first pattern and the second pattern in the layer of photosensitive resin; and
hardening patterned layer of photosensitive resin.

18. The method according to claim 17, wherein a process to pattern the layer of photosensitive resin include a photolithography process.

19. A method for packaging a display panel, using a screen-printing mask with a first pattern with a continuous loop shaped groove surrounding a first area and a second pattern with grooves forming a discontinuous loop surrounding the first pattern, the first pattern being configured to form a sealing loop for the display panel and the second pattern being configured to form a supporting loop to provide support for the first pattern in a display panel packaging process, includes:
applying frit on the screen-printing mask to cover at least the first pattern and the second pattern;
scraping the frit such that only the groove of the first pattern and the grooves of the second pattern are filled with frit;
forming a continuous frit sealing loop through the first pattern and a discontinuous frit supporting loop through the second pattern on a first substrate, the continuous fit sealing loop surrounding a first area on the first substrate;
aligning the first substrate with a second substrate containing an OLED structure and contacting the first substrate with the second substrate so that the OLED structure of the second substrate is placed in an area corresponding to the first area on the first substrate; and
scanning the continuous frit sealing loop with laser to bond the first substrate and the second substrate.

20. The method according to claim 19, further including cutting bonded first substrate and second substrate along periphery of the discontinuous fit supporting loop, along a direction of the discontinuous frit supporting loop, or along an area between the discontinuous first supporting loop and the continuous frit sealing loop to remove excessive portions of the first substrate and the second substrate.

21. The method according to claim 19, wherein forming the continuous frit sealing loop through the first pattern and the discontinuous frit supporting loop through the second pattern on the first substrate includes flipping the mask for screen printing onto the first substrate to transfer the continuous frit sealing loop through the first pattern and transfer the discontinuous frit supporting loop through the second pattern.

22. The method according to claim 19, further including a baking process to harden the continuous frit sealing loop and the discrete frit supporting loop after the continuous frit sealing loop and the discrete frit supporting loop are formed on the first substrate.

23. The method according to claim 22, wherein a baking temperature is about 350 degrees Celsius to about 450 degrees Celsius.

24. The method according to claim 19, wherein thicknesses of the continuous frit sealing loop and the discrete frit supporting loop is same.
